(19) United States
(12) Patent Application Publication
(10) Pub. No.: US 2022/0143834 A1
(43) Pub. Date: May 12, 2022

(54) HOLDING DEVICE, ROBOT WITH THE SAME, AND METHOD OF CONTROLLING HOLDING DEVICE

(71) Applicant: Kawasaki Jukogyo Kabushiki Kaisha, Kobe-shi, Hyogo (JP)

(72) Inventor: Tatsuhiro UTO, Kobe-shi, Hyogo (JP)

(73) Assignee: Kawasaki Jukogyo Kabushiki Kaisha, Kobe-shi, Hyogo (JP)

(21) Appl. No.: 17/439,405

(22) PCT Filed: May 29, 2020
(86) PCT No.: PCT/JP2020/021397

§ 371 Date: Sep. 15, 2021

(30) Foreign Application Priority Data
May 31, 2019 (JP) 2019-102699

(51) Int. Cl. B25J 9/16; H05K 13/04; B25J 15/00

(52) U.S. Cl. CPC B25J 9/1682; B25J 15/0028; H05K 13/0408

(57) ABSTRACT

The present disclosure includes a first holding mechanism which has a pair of first members relatively movable in a first direction, and can hold an electronic component by pinching the electronic component in the first direction by the pair of first members, and a second holding mechanism which has a pair of second members relatively movable in a second direction, and can hold the electronic component by pinching the electronic component in the second direction by the pair of second members. A controlling device controls operations of the first and second holding mechanisms so that the electronic component is released from the first holding mechanism after or in the middle of holding the electronic component by the second holding mechanism in a state where the electronic component is held by the first holding mechanism.

### TECHNICAL FIELD

The present disclosure relates to a holding device, a robot with the same, and a method of controlling the holding device.

### BACKGROUND ART

Conventionally, a holding device for holding an electronic component is known. Such a holding device is proposed as an electronic component insertion apparatus of Patent Document 1, for example.

The electronic component insertion apparatus of Patent Document 1 includes a transferring means for holding an electronic component and transferring it to a given position, a lead wire bending correcting means for correcting bending of lead wires of the electronic component transferred by the transferring means, and a pinching means for receiving the electronic component from the transferring means, bending the lead wires after cutting tip-end parts of the lead wires, and pinching the lead wires into given holes of a substrate.

### REFERENCE DOCUMENT OF CONVENTIONAL ART

[Patent Document]
[Patent Document 1] JP1993-218691A

### DESCRIPTION OF THE DISCLOSURE

### Problem to be Solved by the Disclosure

However, the electronic component insertion apparatus of Patent Document 1 may not securely transfer the electronic component from the transferring means to the pinching means.

Therefore, one purpose of the present disclosure is to provide a holding device, a robot with the same, and a method of controlling the holding device, which are capable of securely transferring an electronic component from a first holding mechanism to a second holding mechanism.

### SUMMARY OF THE DISCLOSURE

In order to solve the problem, a holding device according to the present disclosure holds an electronic component, and includes a first holding mechanism having a pair of first members opposing to each other in a first direction and relatively movable in the first direction, and configured to hold the electronic component by pinching the electronic component in the first direction by the pair of first members, a second holding mechanism having a pair of second members opposing to each other in a second direction different from the first direction and relatively movable in the second direction, and configured to hold the electronic component by pinching the electronic component in the second direction by the pair of second members, and a controlling device configured to control operations of the first and second holding mechanisms. The controlling device controls the operations of the first and second holding mechanisms so that the electronic component is released from the first holding mechanism after or in the middle of holding the electronic component by the second holding mechanism in a state where the electronic component is held by the first holding mechanism.

According to this configuration, the holding device according to the present disclosure transfers the electronic component from the first holding mechanism which is capable of holding the electronic component by pinching the electronic component by the pair of first members in the first direction, to the second holding mechanism which is capable of holding the electronic component by pinching the electronic component E by the pair of second members in the second direction different from the first direction. As a result, the holding device according to the present disclosure becomes possible to securely transfer the electronic component from the first holding mechanism to the second holding mechanism.

The electronic component may have an electronic component body, and a lead wire extending from the electronic component body. The first holding mechanism may hold the electronic component by pinching, by the pair of first members, the lead wire in a radial direction of the lead wire that is in agreement with the first direction. The second holding mechanism may hold the electronic component by pinching, by the pair of second members, the electronic component body in a height direction of the electronic component body that is in agreement with the second direction.

According to this configuration, even when the electronic component has the electronic component body and the lead wire extending from the electronic component body, the electronic component can securely be transferred from the first holding mechanism to the second holding mechanism.

The electronic component may have a plurality of lead wires, and the plurality of lead wires may be arranged parallelly in a parallelly-arranged direction that is in agreement with the first direction and the radial direction of the lead wires. The first holding mechanism may hold the electronic component by pinching, by the pair of first members, the plurality of lead wires in the parallelly-arranged direction from outside in the parallelly-arranged direction.

According to this configuration, even when the electronic component has the plurality of lead wires, the electronic component can securely be transferred from the first holding mechanism to the second holding mechanism.

The electronic component body may have a corner part at least in one of both ends in the height direction. The pair of second members may have a recess of a shape corresponding to the corner part. The second holding mechanism may hold the electronic component in a state where the corner part is fitted into the recess.

According to this configuration, since the second holding mechanism can hold the electronic component in the state where the corner part is fitted into the recess, the electronic component can be transferred further securely from the first holding mechanism to the second holding mechanism.

A plurality of first holding mechanisms may be provided.

According to this configuration, the electronic component can efficiently be transferred from the first holding mechanism to the second holding mechanism.

For example, when holding the electronic component, the first holding mechanism may apply a first external force to the electronic component from each of the pair of first members. When holding the electronic component, the second holding mechanism may apply a second external force to the electronic component from each of the pair of second members. The second external force may have a magnitude capable of moving in the second direction the electronic component held by the first holding mechanism, against the first external force.

The second direction may be perpendicular to the first direction.

According to this configuration, the electronic component can be transferred further securely from the first holding mechanism to the second holding mechanism.

In order to solve the problem, a robot according to the present disclosure includes the holding device having any one of the configurations described above, a first robotic arm provided with the first holding mechanism at a tip end thereof and having at least one joint axis, a second robotic arm provided with the second holding mechanism at a tip end thereof and having at least one joint axis, and a robot controlling device configured to control operations of the first and second robotic arms.

According to this configuration, since the holding device having any one of the configurations described above is provided, the electronic component can securely be transferred from the first holding mechanism to the second holding mechanism.

Rotation axes of the first and second robotic arms at base ends thereof may be located on the same straight line.

According to this configuration, the robot can be reduced in size.

The controlling device may be configured as a part of the robot controlling device.

According to this configuration, the configuration of the robot according to the present disclosure can be simplified.

The at least one joint axis of the first robotic arm may be provided with a first servomotor configured to rotate itself, and the at least one joint axis of the second robotic arm may be provided with a second servomotor configured to rotated itself. The first holding mechanism may be provided with a third servomotor configured to drive the pair of first members, and the second holding mechanism may be provided with a fourth servomotor configured to drive the pair of second members. The controlling device may be configured as a part of the robot controlling device, and the robot controlling device may servo-control the first and second robotic arms, and the first and second holding mechanisms by using the first to fourth servomotors.

According to this configuration, the configuration of the robot according to the present disclosure can be simplified and it becomes possible to accurately control the operation of the robot.

In order to solve the problem, a method of controlling a holding device according to the present disclosure is a method of controlling a holding device configured to hold an electronic component, the holding device including a first holding mechanism having a pair of first members opposing to each other in a first direction and relatively movable in the first direction, and configured to hold the electronic component by pinching the electronic component in the first direction by the pair of first members, a second holding mechanism having a pair of second members opposing to each other in a second direction different from the first direction and relatively movable in the second direction, and configured to hold the electronic component by pinching the electronic component in the second direction by the pair of second members, and a controlling device configured to control operations of the first and second holding mechanisms. The method includes the steps of holding the electronic component by the first holding mechanism (First Step), and releasing the electronic component from the first holding mechanism, after or in the middle of holding the electronic component by the second holding mechanism (Second Step).

According to this configuration, the method of controlling the holding device according to the present disclosure transfers the electronic component from the first holding mechanism which is capable of holding the electronic component by pinching the electronic component by the pair of first members in the first direction, to the second holding mechanism which is capable of holding the electronic component by pinching the electronic component E by the pair of second members in the second direction different from the first direction. As a result, the method of controlling the holding device according to the present disclosure becomes possible to securely transfer the electronic component from the first holding mechanism to the second holding mechanism.

### Effect of the Disclosure

According to the present disclosure, a holding device, a robot with the same, and a method of controlling the holding device can be provided, which are capable of securely transferring an electronic component from a first holding mechanism to a second holding mechanism.

### BRIEF DESCRIPTION OF DRAWINGS

FIG. 1 is a schematic view illustrating a situation where a holding device according to one embodiment of the present disclosure and a robot provided with the same perform a transferring work of electronic components.

FIG. 2 is a front view illustrating an entire configuration of the holding device according to one embodiment of the present disclosure, and the robot provided with the same.

FIG. 3 is a front view of first holding mechanisms provided to the holding device according to one embodiment of the present disclosure.

FIG. 4 is a front view of second holding mechanisms provided to the holding device according to one embodiment of the present disclosure.

FIG. 5 is a block diagram illustrating a robot controlling device provided to the robot according to one embodiment of the present disclosure.

FIGS. 6(A) and 6(B) are partial schematic views illustrating a situation where a plurality of electronic components transferred by the holding device according to one embodiment of the present disclosure and the robot provided with the same are accommodated in a first accommodating device, where FIG. 6(A) is a plan view and FIG. 6(B) is a VIB direction view illustrated in FIG. 6(A).

FIGS. 7(A) and 7(B) are partial schematic views illustrating a situation where the holding device according to one embodiment of the present disclosure holds the electronic components by the first holding mechanisms, where FIG. 7(A) is a view when the first holding mechanisms are located above the electronic components, FIG. 7(B) is a view when the electronic components are held by the first holding mechanisms, and FIG. 7(C) is a view when the first holding mechanisms are raised while holding the electronic components.

FIGS. 8(A) and 8(B) are schematic views illustrating a situation where the holding device according to one embodiment of the present disclosure holds, by the second holding mechanism, the electronic component which is held by the first holding mechanism, where FIG. 8(A) is a view when the second holding mechanism opposes horizontally to the electronic component, and FIG. 8(B) is a view when the electronic component is held by the second holding mechanism.

FIGS. 9(A) and 9(B) are schematic views illustrating a situation where the holding device according to one embodiment of the present disclosure transfers the electronic component from the first holding mechanism to the second holding mechanism, where FIG. 9(A) is a view immediately before the electronic component is released from the first holding mechanism, and FIG. 9(B) is a view illustrating a state where the electronic component is held by the second holding mechanism at the time of FIG. 9(A).

FIGS. 10(A) and 10(B) are schematic views illustrating a situation where the holding device according to one embodiment of the present disclosure transfers the electronic component from the first holding mechanism to the second holding mechanism, where FIG. 10(A) is a view immediately after the electronic component is released from the first holding mechanism, and FIG. 10(B) is a view illustrating a state where the electronic component is held by the second holding mechanism at the time of FIG. 10(A).

FIGS. 11(A) and 11(B) are schematic views illustrating a situation where the second holding mechanisms are separated from the first holding mechanism after the holding device according to one embodiment of the present disclosure transfers the electronic component from the first holding mechanism to the second holding mechanism, where FIG. 11(A) is a view immediately after one of the second holding mechanisms is separated from the first holding mechanism, and FIG. 11(B) is a view immediately after the other second holding mechanism is separated from the first holding mechanism.

FIGS. 12(A) and 12(B) are partial schematic views illustrating a situation where a plurality of electronic components transferred by the holding device according to one embodiment of the present disclosure and the robot provided with the same are accommodated in a second accommodating device, where FIG. 12(A) is a plan view and FIG. 12(B) is a XIIB direction view illustrated in FIG. 12(A).

FIG. 13 is a flowchart illustrating a controlling method for controlling operation of the holding device according to one embodiment of the present disclosure.

FIGS. 14(A) and 14(B) are schematic views illustrating a situation where a first modification of the holding device according to one embodiment of the present disclosure and the robot provided with the same transfers the electronic component from the first holding mechanism to the second holding mechanism, where FIG. 14(A) is a view immediately before the electronic component is released from the first holding mechanism, and FIG. 14(B) is a view illustrating a state where the electronic component is about to be held by the second holding mechanism at the time of FIG. 14(A).

FIGS. 15(A) and 15(B) are schematic views illustrating a situation where a second modification of the holding device according to one embodiment of the present disclosure and the robot provided with the same transfers the electronic component from the first holding mechanism to the second holding mechanism, where FIG. 15(A) is a view immediately before the electronic component is released from the first holding mechanism, and FIG. 15(B) is a view illustrating a state where the electronic component is held by the second holding mechanism at the time of FIG. 15(A).

FIGS. 16(A) and 16(B) are schematic views illustrating a situation where a third modification of the holding device according to one embodiment of the present disclosure and the robot provided with the same transfers the electronic component from the first holding mechanism to the second holding mechanism, where FIG. 16(A) is a view immediately before the electronic component is released from the first holding mechanism, and FIG. 16(B) is a view illustrating a state where the electronic component is held by the second holding mechanism at the time of FIG. 16(A).

### MODES FOR CARRYING OUT THE DISCLOSURE

(Entire Configuration)

Hereinafter, a holding device according to one embodiment of the present disclosure and a robot provided with the same are described with reference to the drawings. Note that the present disclosure is not necessarily limited by this embodiment. Moreover, below, throughout the drawings, the same reference characters are assigned to the same or corresponding elements to omit redundant description.

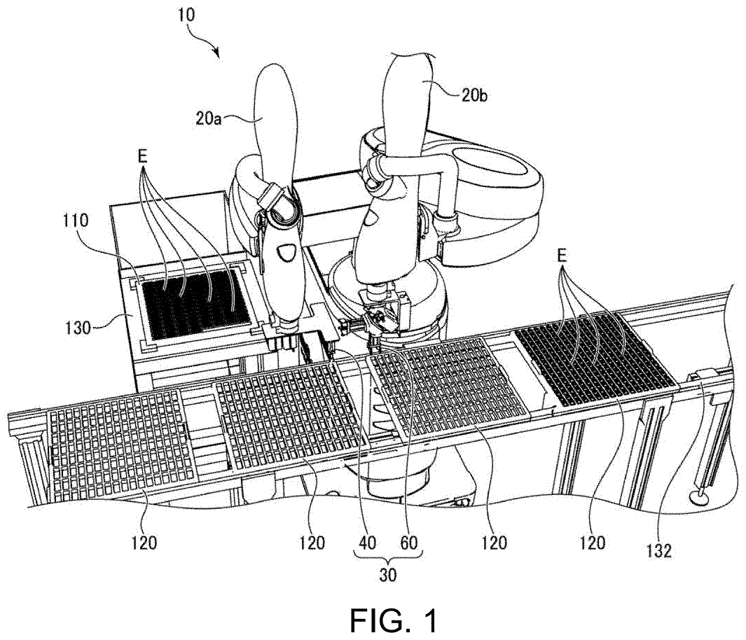

FIG. 1 is a schematic view illustrating a situation where the holding device according to this embodiment and the robot provided with the same perform a transferring work of an electronic component. As illustrated in FIG. 1, a holding device 30 according to this embodiment and a robot 10 provided with the same are used for transferring a plurality of electronic components E from a first accommodating device 110 to a second accommodating device 120. Note that FIG. 1 illustrates a state where one second accommodating device 120 after the electronic components E are accommodated by the robot 10 is located at the downstream end (that is, the rightmost in the drawing) of a conveyor 132 for conveying a plurality of second accommodating devices 120 one by one, and one second accommodating device 120 where the electronic components E are being accommodated by the robot 10 is located at the second one from the downstream end (that is, the second one from the rightmost in the drawing) of the conveyor 132.

(Robot 10)

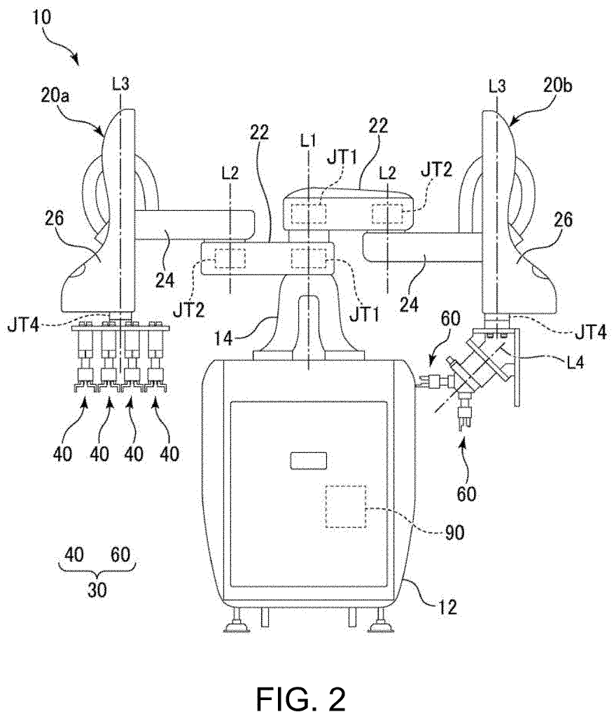

FIG. 2 is a front view illustrating the entire configuration of the holding device according to this embodiment and the robot provided with the same. As illustrated in FIG. 2, the robot 10 according to this embodiment includes a pedestal 12, a pair of robotic arms 20a and 20b (a first robotic arm and a second robotic arm) supported by the pedestal 12, and the holding device 30 provided to tip ends of the pair of robotic arms 20a and 20b. Moreover, the robot 10 further includes a robot controlling device 90 (illustrated by a broken line in FIG. 2) provided to the pedestal 12.

(Pair of Robotic Arms 20a and 20b)

Each of the pair of robotic arms 20a and 20b is a horizontal articulated robotic arm configured to be movable with respect to the pedestal 12. The pair of robotic arms 20a and 20b can operate independently or can operate collaboratively. Note that the robotic arm 20b has the same structure as the robotic arm 20a. Therefore, here, only the robotic arm 20a is described except for the case of being particularly required, and description which becomes the same as the robotic arm 20b will not be repeated.

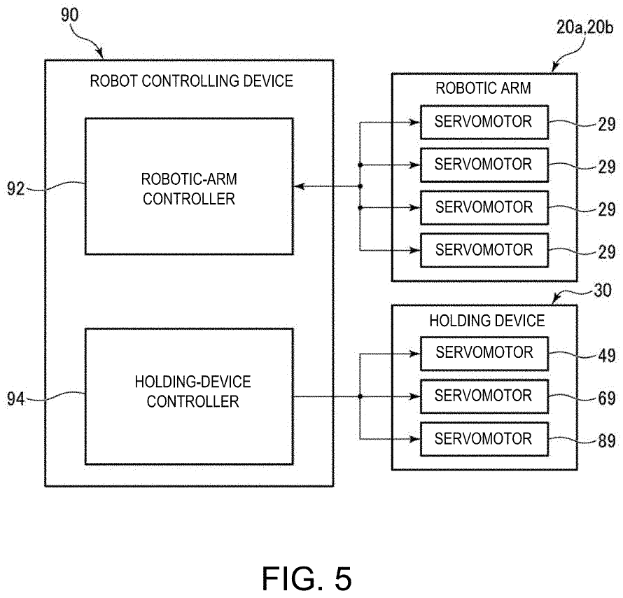

The robotic arm 20a has joint axes JT1-JT4. Drive servomotors 29 (see FIG. 5, first servomotors) are provided to the robotic arm 20a so as to correspond to the joint axes JT1-JT4. The robotic arm 20a has a first link 22, a second link 24, and a wrist 26.

The first link 22 is coupled to a base shaft 14 fixed to an upper surface of the pedestal 12 through the joint axis JT1 so as to be rotatable on a rotation axis L1 which is defined to pass through the axial center of the base shaft 14. The second link 24 is coupled to a tip end of the first link 22 through the joint axis JT2 so as to be rotatable on a rotation axis L2 which is defined at the tip end of the first link 22.

The wrist 26 has a mechanical interface 27 to which a first holding mechanism 40 (described later) is attached, and is coupled to a tip end of the second link 24 through the linear-motion joint axis JT3 (not illustrated) and through the rotary-motion joint axis JT4. The wrist 26 is movable upward and downward with respect to the second link 24 by the linear-motion joint axis JT3. Moreover, the wrist 26 is rotatable on a rotation axis L3 perpendicular to the second link 24 through the rotary-motion joint axis JT4.

As for the robotic arms 20a and 20b, the rotation axes L1 at their base ends are located on the same straight line. Note that the first link 22 of the robotic arm 20a and the first link 22 of the robotic arm 20b are disposed with a vertical difference therebetween.

(Holding Device 30)

As illustrated in FIG. 2, the holding device 30 according to this embodiment includes four first holding mechanisms 40 provided to the tip end of the robotic arm 20a, and two second holding mechanisms 60 provided to the tip end of the robotic arm 20b.

(First Holding Mechanism 40)

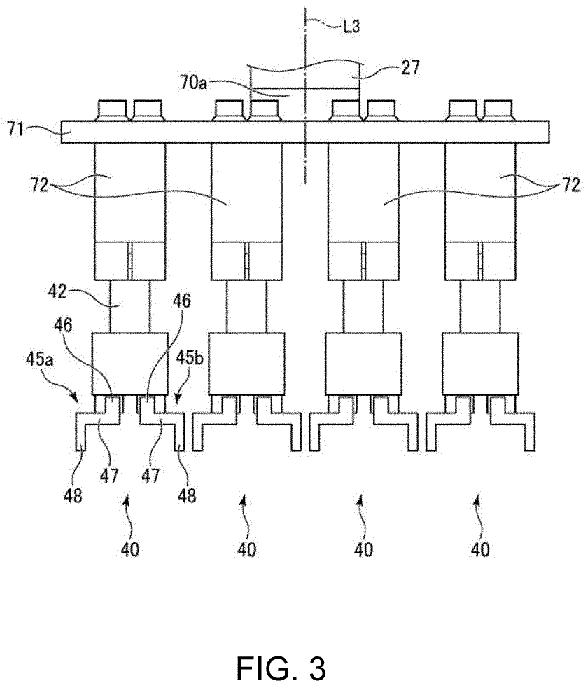

FIG. 3 is a front view of the first holding mechanisms provided to the holding device according to this embodiment. As illustrated in FIG. 3, the holding device 30 according to this embodiment further includes an attaching part 70a to which the mechanical interface 27 of the robotic arm 20a (first robotic arm) is attached to a base end thereof and which is rotatable on the rotation axis L3, and a base shaft member 71 provided to a tip end of the attaching part 70a. The attaching part 70a is formed in a cylindrical shape with the dimension and a shape corresponding to the mechanical interface 27. The base shaft member 71 is formed in a plate shape and extends horizontally.

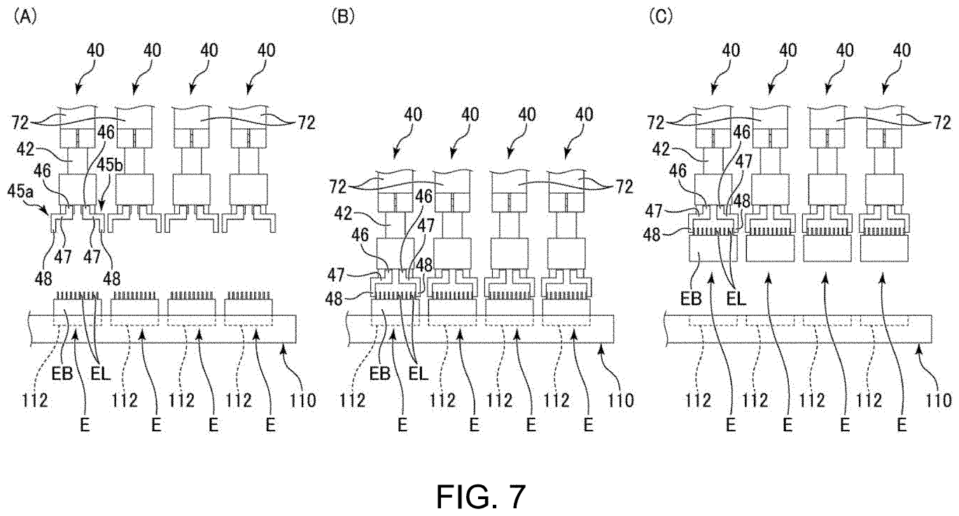

The holding device 30 according to this embodiment further includes four center members 72 which are lined up in the axial direction of the base shaft member 71, and which are fixed at their base ends to the bottom surface of the base shaft member 71 and extend downwardly. A base end of the first holding mechanism 40 is fixed to a tip end of each of the four center members 72. Note that the four first holding mechanisms 40 have mutually the same structure. Therefore, here, except for the case of being particularly required, only the first holding mechanism 40 located at the leftmost in FIG. 3 is attached with a reference character in detail and is described, and the remaining three first holding mechanisms 40 are not attached with the detailed reference characters without repeating similar description. Note that similar things are applied to FIGS. 7(A) and 7(B) (described later).

As illustrated in FIG. 3, the first holding mechanism 40 includes a shaft member 42 which is fixed at its base end to a tip end of the center member 72 and extends vertically, and a pair of first members 45a and 45b provided to a tip end of the shaft member 42.

The pair of first members 45a and 45b each includes a base-end part 46 which is fixed at a base end thereof to the tip end of the shaft member 42 and extends vertically, a center part 47 which is bent outwardly (that is, outside when seen from the axis of the shaft member 42) from a tip end of the base-end part 46 and extends horizontally, and a tip-end part 48 which is bent from a tip end of the center part 47 and extends vertically.

The pair of first members 45a and 45b oppose to each other in the left-and-right direction (first direction) in FIG. 3 and are relatively movable in the same direction. The pair of first members 45a and 45b are each driven by a servomotor 49 (see FIG. 5, a third servomotor) provided inside the shaft member 42, and are movable oppositely in the left-and-right direction in FIG. 3. The pair of first members 45a and 45b may be movable oppositely in the left-and-right direction in FIG. 3 by each being provided with a so-called “rack and pinion” structure having the servomotor 49.

In detail, a pinion (not illustrated) is attached to a rotation shaft of the servomotor 49, for example. Two racks (the same as above) mesh with the pinion. One of the two racks meshes with a part of the pinion on one side in the radial direction (for example, a lower part in FIG. 3). The base-end part 46 of the first member 45a is fixed to the one rack. Moreover, the other of the two racks meshes with a part of the pinion on the other side in the radial direction (for example, an upper part in FIG. 3). The base-end part 46 of the first member 45b is fixed to the other rack.

The first holding mechanism 40 is configured so that the two racks move oppositely in the left-and-right direction in FIG. 3 by the pinion being rotated by the servomotor 49. According to the above structure, the first member 45a attached to one of the racks and the first member 45b attached to the other rack become movable oppositely to each other in the left-and-right direction in FIG. 3.

(Second Holding Mechanism 60)

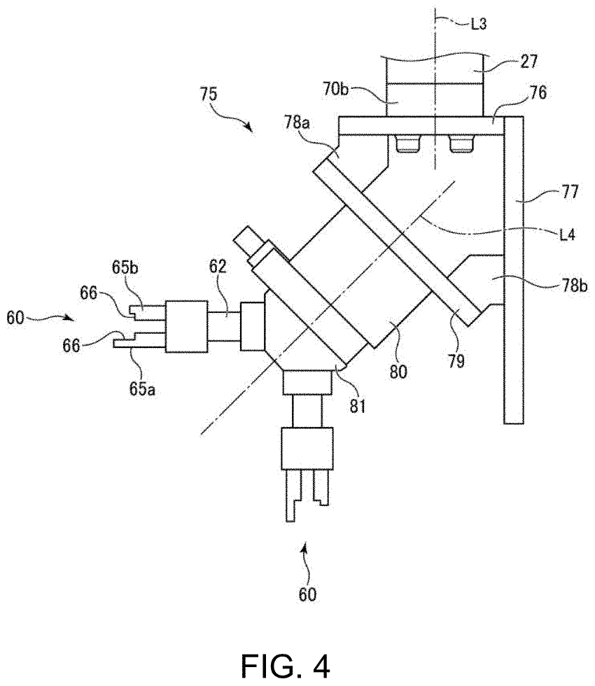

FIG. 4 is a front view of the second holding mechanisms provided to the holding device according to this embodiment. As illustrated in FIG. 4, the holding device 30 according to this embodiment further includes an attaching part 70b which is attached to the mechanical interface 27 of the robotic arm 20b (second robotic arm) and is rotatable on the rotation axis L3, and an intervening mechanism 75 provided to a tip end of the attaching part 70b.

The attaching part 70b is formed in a cylindrical shape with the dimension and a shape corresponding to the mechanical interface 27. The intervening mechanism 75 includes a first base-end member 76 which is fixed to the tip end of the attaching part 70b and extends horizontally, and a second base-end member 77 which extends downwardly from an edge part on one of the first base-end member 76 in the horizontal direction (in FIG. 4, a right edge). The first base-end member 76 and the second base-end member 77 are each formed in a plate shape.

The intervening mechanism 75 further includes a connecting member 78a provided to a bottom surface of an edge part of the first base-end member 76 on the other side in the horizontal direction (in FIG. 4, a left edge), and a connecting member 78b provided to the left side surface in FIG. 4 of the center part of the second base-end member 77 in the up-and-down direction. Moreover, the intervening mechanism 75 further includes a plate-like member 79 which is connected at one end of its upper surface to the first base-end member 76 through the connecting member 78a and connected at the other end of the upper surface to the second base-end member 77 through the connecting member 78b, a casing 80 provided to a bottom surface of the plate-like member 79, a rotation shaft (not illustrated) which is located at its base-end part inside the casing 80 and protrudes at its tip-end part from a bottom surface of the casing 80, and a tip-end member 81 attached to a tip end of the rotation shaft.

When seen in the side view as illustrated in FIG. 4, the plate-like member 79 extends so that its upper surface and bottom surface make an angle of 45° from the left-and-right direction in FIG. 4. Moreover, the casing 80, the rotation shaft provided to the casing 80, and the tip-end member 81 are arranged so that their center rotation axes L4 are located on the same straight line. When seen in the side view as illustrated in FIG. 4, the casing 80, the rotation shaft provided to the casing 80, and the tip-end member 81 are arranged so that their center rotation axes L4 make an angle of 45° from the left-and-right direction in FIG. 4. The rotation shaft provided to the casing 80 and the tip-end member 81 are each driven by a servomotor 89 (see FIG. 5) provided inside the casing 80, and rotatable on the center rotation axis L4.

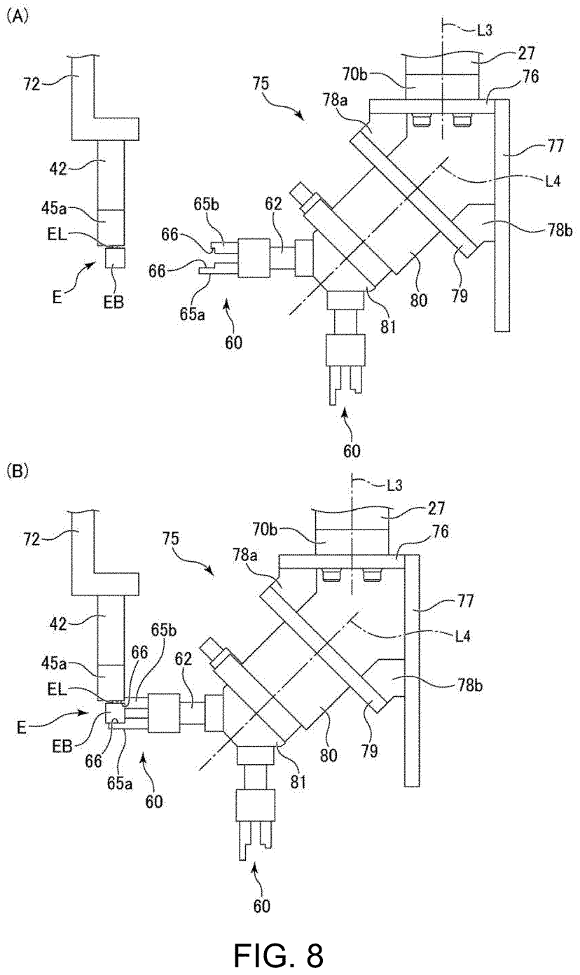

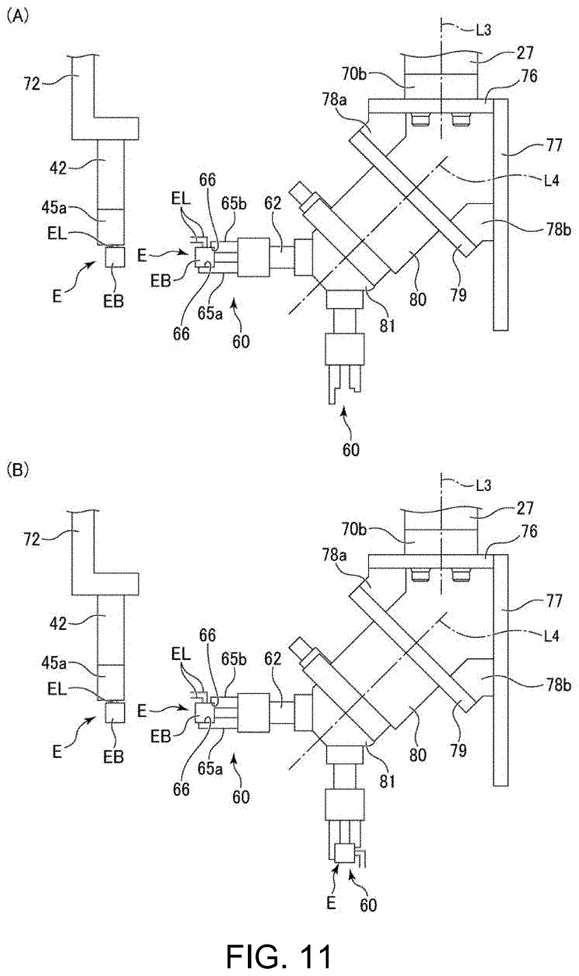

The base ends of the two second holding mechanisms 60 are fixed to the inside of the tip-end member 81. One of the two second holding mechanisms 60 extends horizontally. The other of the two second holding mechanisms 60 extends vertically. Note that the two second holding mechanisms 60 have the same structure as each other. Therefore, here, except for the case of being particularly required, only one of the two second holding mechanisms 60 (that is, the second holding mechanism 60 extending horizontally) is described while attaching the reference character in detail, not to repeat similar description for the other of the two second holding mechanisms 60 (that is, the second holding mechanism 60 extending vertically), without attaching the detailed reference character. Note that similar things can be said for FIGS. 8 and 11 (described later).

As illustrated in FIG. 4, the second holding mechanism 60 includes a shaft member 62 which is fixed at its base end to the tip-end member 81 and extends horizontally, and a pair of second members 65a and 65b provided to a tip end of the shaft member 62. The pair of second members 65a and 65b are each formed in a plate shape, and extends horizontally. The pair of second members 65a and 65b is each attached at a base end to the shaft member 62, and has a recess 66 at its tip end, which has a shape corresponding to a corner part EC of an electronic component body EB (described later).

The pair of second members 65a and 65b oppose to each other in the up-and-down direction (second direction) in FIG. 4 and are relatively movable in the same direction. The pair of second members 65a and 65b are each driven by a servomotor 69 (see FIG. 5, a fourth servomotor) provided inside the shaft member 62, and they are movable oppositely in the up-and-down direction in FIG. 4. The pair of second members 65a and 65b may be movable oppositely in the up-and-down direction in FIG. 5 by each having a so-called “rack and pinion structure” similar to the pair of first members 45a and 45b described above.

(Robot Controlling Device 90)

FIG. 5 is a block diagram illustrating a robot controlling device provided to the robot according to this embodiment. As illustrated in FIG. 5, the robot controlling device 90 includes a robotic-arm controller 92 for controlling operation of the robotic arm 20, and a holding-device controller 94 (controlling device) for controlling operation of the holding device 30. That is, the robotic-arm controller 92 and the holding-device controller 94 are each configured to be a part of the robot controlling device 90.

The robotic-arm controller 92 carries out a servo control of the robotic arm 20a by using the four servomotors 29 (first servomotor) provided to the robotic arm 20a. Moreover, the robotic-arm controller 92 carries out a servo control of the robotic arm 20b by using the four servomotors 29 (second servomotor) provided to the robotic arm 20b.

The holding-device controller 94 carries out a servo control of the four first holding mechanisms 40 by using the servomotors 49 (third servomotor) provided to the four first holding mechanisms 40, respectively. Moreover, the holding-device controller 94 carries out a servo control of the second holding mechanism 60 by using the servomotor 69 (fourth servomotor) and the servomotor 89 provided to the two second holding mechanisms 60, respectively.

As described above, the robot controlling device 90 can carry out a servo control of the robotic arms 20a and 20b (first and second robotic arms), the first holding mechanism 40, and the second holding mechanism 60 by using the servomotors 29, 49, 69, and 89 (first to fourth servomotors).

Note that, in order to avoid the complication of the appearance, only the four servomotors 29 provided to the robotic arms 20a and 20b are connected to the robotic-arm controller 92 in FIG. 5, but actually eight servomotors 29 provided to the robotic arms 20a and 20b are connected to the robotic-arm controller 92. Moreover, one servomotor 49 and one servomotor 69 are connected to the holding-device controller 94, but actually four servomotors 49 and two servomotors 69 are connected to the holding-device controller 94.

Although the concrete configuration of the robot controlling device 90 is not limited in particular, it may be implemented by a CPU (Central Processing Unit) operating according to a program stored in a memory, for example.

(One Example of Transferring Work of Electronic Component E)

Next, one example of the transferring work of the electronic component E which is performed using the holding device 30 and the robot 10 provided with the same is described mainly based on FIGS. 1 and 6 to 12. Here, one example of the work for transferring the plurality of electronic components E from the first accommodating device 110 to the second accommodating device 120 by using the holding device 30 and the robot 10 provided with the same at a worksite illustrated in FIG. 1 is described.

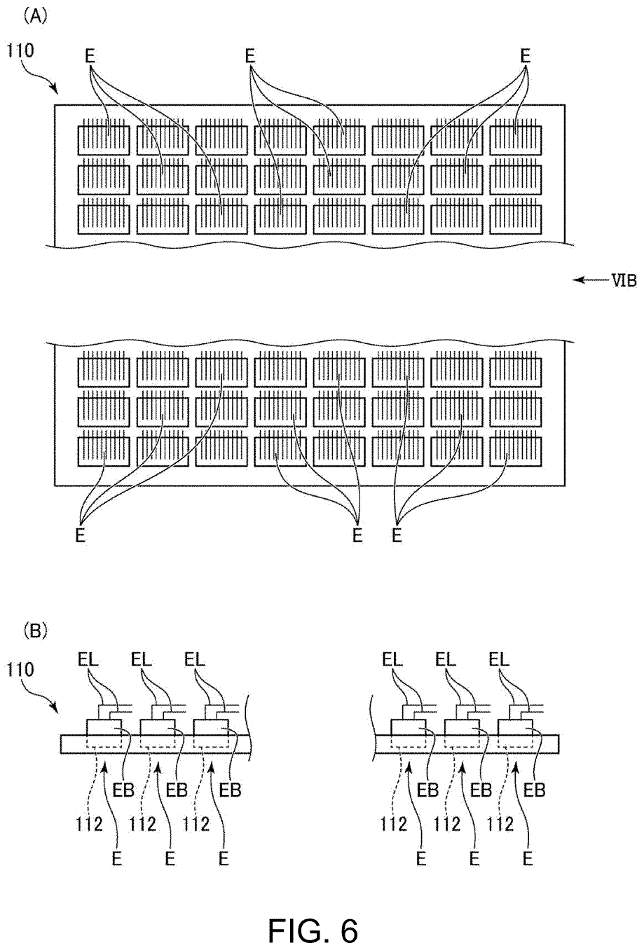

FIGS. 6(A) and 6(B) are partial schematic views illustrating a situation where the plurality of electronic components transferred by the holding device according to this embodiment and the robot provided with the same are accommodated in the first accommodating device, where FIG. 6(A) is a plan view and FIG. 6(B) is a VIB direction view illustrated in FIG. 6(A). For example, the first accommodating device 110 illustrated in FIGS. 6(A) and 6(B) is conveyed to the worksite illustrated in FIG. 1 by being loaded on a conveying body (for example, a ship or a vehicle), after it accommodates the plurality of electronic components E at a manufacturing site (not illustrated) of the electronic components E. The first accommodating device 110 conveyed to the worksite is placed on a loading table 130 by a human labor. The loading table 130 is disposed adjacent to the conveyor 132 for continuously conveying a plurality of second accommodating devices 120 at a constant interval.

As illustrated in FIG. 6(A), the first accommodating device 110 can accommodate the plurality of electronic components E parallelly in a matrix shape. In detail, the first accommodating device 110 accommodates the total of one-hundred-twenty electronic components E in a matrix of 8×15 by parallelly arranging eight electronic components E in the left-and-right direction of the drawing sheet of FIG. 6(A) and parallelly arranging 15 electronic components E in the up-and-down direction of the drawing sheet of the same drawing.

Here, as illustrated in FIG. 6(B), the electronic component E has an electronic component body EB, and lead wires EL extending from the electronic component body EB.

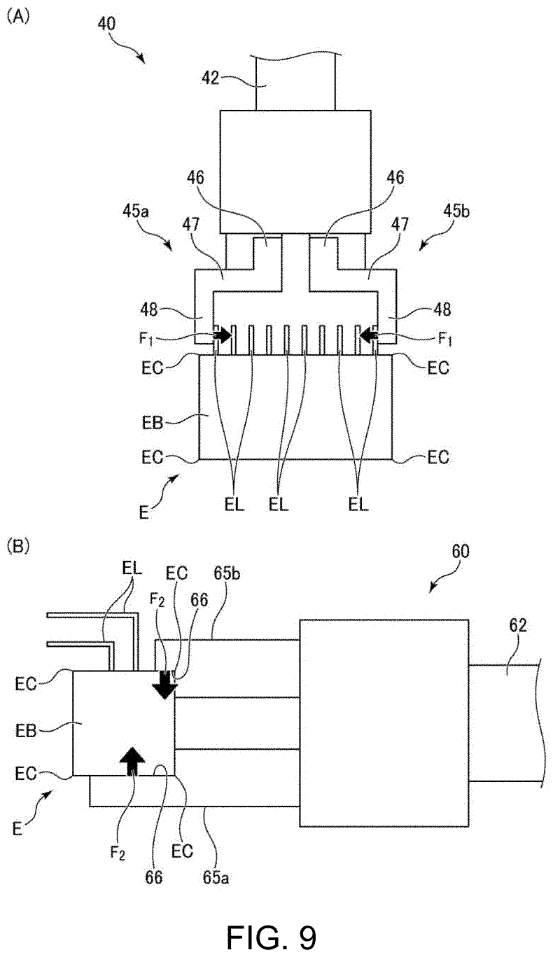

The electronic component body EB is formed in a rectangular parallelepiped shape, and has a longitudinal direction (first direction) which is in agreement with a depth direction of the drawing sheet of FIG. 6(B), a front-and-rear direction which is in agreement with the left-and-right direction of the drawing sheet of the same drawing, and a height direction (second direction) which is in agreement with the up-and-down direction of the drawing sheet of the same drawing. The electronic component body EB has the corner part EC (see FIG. 9 etc.) at both ends in the height direction.

Twenty lead wires EL are provided to an upper surface of the electronic component body EB. When seen in the side view as illustrated in FIG. 6(B), each of the twenty lead wires EL is formed in an L-shape having a part extending upwardly from the upper surface of the electronic component body EB, and a part which is bent from an upper end of the upwardly-extending part and extends toward the front surface of the electronic component body EB.

Ten lead wires among the twenty lead wires EL are arranged parallelly in the depth direction of the drawing sheet of the same drawing in a left part of the upper surface of the electronic component body EB in FIG. 6(B). The depth direction is in agreement with the radial direction of the twenty lead wires EL. The remaining ten among the twenty lead wires EL are arranged parallelly in the depth direction of the drawing sheet of the same drawing in a right part of the upper surface of the electronic component body EB of the same drawing. The depth direction is in agreement with the radial direction (the same as above) of the remaining twenty lead wires EL.

As illustrated in FIG. 6(B), the height dimension of the ten lead wires EL of the front row is smaller than the height dimension of the ten lead wires of the rear row. Moreover, as illustrated in FIG. 6(A), since the ten lead wires EL of the front row and the ten lead wires EL of the rear row are located parallelly at the same positions in the left-and-right direction of the same drawing, the ten lead wires EL of the rear row are hidden by the ten lead wires EL of the front row, and, therefore, they cannot be visible in the same drawing.

As illustrated in FIG. 6(B), in order to accommodate the electronic components E parallelly in the matrix of 8×15, the first accommodating device 110 has the total of one-hundred-twenty dents 112 of a shape corresponding to a lower part of the electronic component body EB, in the matrix of 8×15. As illustrated in the same drawing, the first accommodating device 110 can accommodate the one-hundred-twenty electronic components E in a state where the lower part of each electronic component body EB is fitted into the dent 112, and the upper part of each electronic component body EB and the twenty lead wires EL are exposed.

FIGS. 7(A) and 7(B) are partial schematic views illustrates a situation where the holding device according to this embodiment holds the electronic components by the first holding mechanisms, where FIG. 7(A) is a view when the first holding mechanisms are located above the electronic components, FIG. 7(B) is a view when the electronic components are held by the first holding mechanisms, and FIG. 7(C) is a view when the first holding mechanisms are raised while holding the electronic components.

As illustrated in FIG. 7(A), the robot controlling device 90 controls operation of the robotic arm 20 so that the four first holding mechanisms 40 are located above the electronic components E accommodated in the first accommodating device 110. In detail, the robot controlling device 90 locates the four first holding mechanisms 40 above the four electronic components E by changing the posture of the robotic arm 20a so that the four first holding mechanisms 40 are located above the four electronic components E arranged parallelly at the 12th to 15th rows of the 8th line in the 8×15 matrix (that is, the four electronic components E at the right end of the closest line in FIG. 1).

Then, as illustrated in FIG. 7(B), the robot controlling device 90 lowers the four first holding mechanisms 40 and makes the four first holding mechanisms 40 hold the electronic components E, respectively. At this time, the robot controlling device 90 makes the four first holding mechanisms 40 hold the electronic components E, respectively, by pinching the twenty lead wires EL in the left-and-right direction in FIG. 7(B) (a parallelly-arranged direction which is in agreement with the first direction and the radial direction of the lead wires), by the pair of first members 45a and 45b from outside in the left-and-right direction.

Moreover, as illustrated in FIG. 7(C), the robot controlling device 90 raises the four first holding mechanisms 40 in a state where the electronic components E are held by the four first holding mechanisms 40, respectively.

FIGS. 8(A) and 8(B) are schematic views illustrating a situation where the holding device according to this embodiment holds the electronic component by the second holding mechanisms in a state where it is held by the first holding mechanism, where FIG. 8(A) is a view when the second holding mechanism opposes horizontally to the electronic component, and FIG. 8(B) is a view when the electronic component is held by the second holding mechanism.

As illustrated in FIG. 8(A), the robot controlling device 90 controls operation of the robotic arm 20 so that one of the second holding mechanisms 60 opposes horizontally to the electronic component E held by the first holding mechanism 40 which is located at the closest side in the depth direction of the drawing sheet of FIG. 8(A).

Then, as illustrated in FIG. 8(B), the robot controlling device 90 moves one of the second holding mechanisms 60 leftward of the drawing sheet of the same drawing to make the one second holding mechanism 60 hold the electronic component E. At this time, the robot controlling device 90 makes the one second holding mechanism 60 hold the electronic component E by pinching the electronic component body EB by the pair of second members 65a and 65b in the up-and-down direction (second direction) in FIG. 8(A).

As described above, the pair of second members 65a and 65b each has the recess 66 of the shape corresponding to the corner part EC (see FIG. 9 etc.) of the electronic component body EB. When pinching the electronic component body EB by the pair of second members 65a and 65b in the up-and-down direction in FIG. 8(A), the robot controlling device 90 controls operations of the robotic arm 20 and the holding device 30 so that the corner part EC of the bottom surface of the electronic component body EB is fitted into the recess 66 of the second member 65a, and the corner part EC of the upper surface of the electronic component body EB is fitted into the recess 66 of the second member 65b.

FIGS. 9(A) and 9(B) are schematic views illustrating a situation where the holding device according to this embodiment transfers the electronic component from the first holding mechanism to the second holding mechanism, where FIG. 9(A) is a view immediately before the electronic component is released from the first holding mechanism, and FIG. 9(B) is a view illustrating a state where the electronic component is held by the second holding mechanism at the time of FIG. 9(A).

As illustrated in FIG. 9(A), when holding the electronic component E, the first holding mechanism 40 applies an external force F₁ (first external force) to the electronic component E from the pair of first members 45a and 45b. In detail, the first holding mechanism 40 holds the electronic component E by applying the external force F₁, by the first member 45a which contacts the lead wires EL among the twenty lead wires EL located at one end (the left end in the same drawing) in the parallelly-arranged direction (first direction) to the lead wires EL toward the other end (the right end in the same drawing) in the parallelly-arranged direction, and by applying the external force F₁, by the first member 45b which contacts the lead wires EL among the twenty lead wires EL located at the other end in the parallelly-arranged direction to the lead wires EL toward the one end in the parallelly-arranged direction.

On the other hand, as illustrated in FIG. 9(B), when holding the electronic component E, the second holding mechanism 60 applies an external force F₂ (second external force) to the electronic component E from each of the pair of second members 65a and 65b. In detail, the second holding mechanism 60 holds the electronic component E by applying the external force F₂, by the second member 65a which contacts the bottom surface of the electronic component body EB, toward the opposite side in the height direction (second direction) of the electronic component body EB (that is, toward the upper surface of the electronic component body EB), and by applying the external force F₂, by the second member 65b which contacts the upper surface of the electronic component body EB, toward the opposite side in the height direction of the electronic component body EB (that is, toward the bottom surface of the electronic component body EB).

As described above, the robot controlling device 90 holds the electronic component E by the second holding mechanism 60 in a state where the electronic component E is held by the first holding mechanism 40. Note that the external force F₁ applied to the electronic component E by the pair of first members 45a and 45b is smaller than the external force F₂ applied to the electronic component E by the pair of second members 65a and 65b.

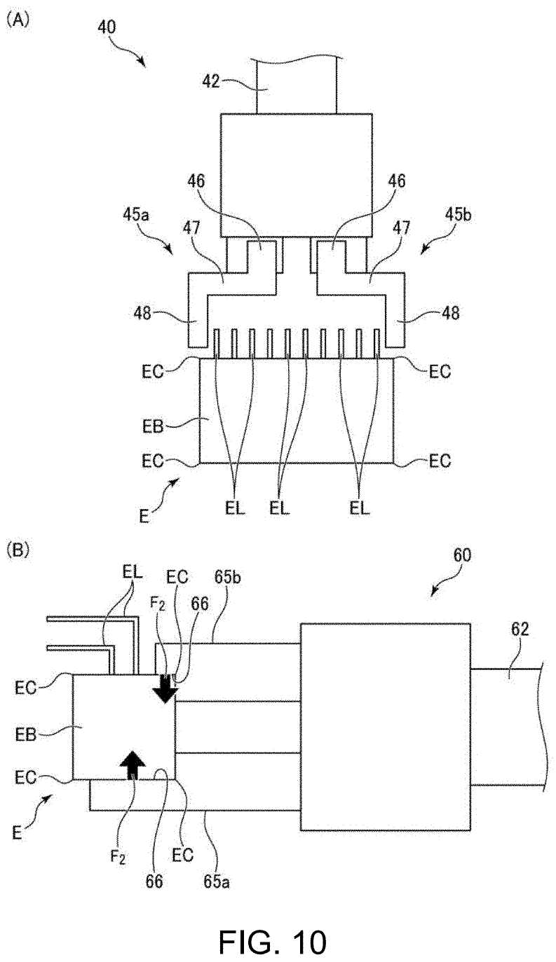

FIGS. 10(A) and 10(B) are schematic views illustrating a situation where the holding device according to this embodiment transfers the electronic component from the first holding mechanism to the second holding mechanism, where FIG. 10(A) is a view immediately after the electronic component is released from the first holding mechanism, and FIG. 10(B) is a view illustrating a state where the electronic component is held by the second holding mechanism at the time of FIG. 10(A).

As illustrated in FIGS. 10(A) and 10(B), the robot controlling device 90 controls operation of the holding device 30 so that, after the electronic component E is held by the second holding mechanism 60 in the state where the electronic component E is held by the first holding mechanism 40, the electronic component E is released from the first holding mechanism 40. As described above, the electronic component E can be transferred from the first holding mechanism 40 located at the closest in the depth direction of the drawing sheet of FIGS. 8(A) and 8(B), to one of the second holding mechanisms 60.

FIGS. 11(A) and 11(B) are schematic views illustrating a situation where the holding device according to this embodiment separates the second holding mechanism from the first holding mechanism after it transfers the electronic component from the first holding mechanism to the second holding mechanism, where FIG. 11(A) is a view immediately after one of the second holding mechanisms is separated from the first holding mechanism, and FIG. 11(B) is a view immediately after the other second holding mechanism is separated from the first holding mechanism.

As illustrated in FIG. 11(A), the robot controlling device 90 separates, from the first holding mechanism 40, one of the second holding mechanisms 60 in the state where it holds the electronic component E, by moving the tip end of the robotic arm 20b rightward of the drawing sheet of the same drawing after transferring, to the one second holding mechanism 60, the electronic component E from the first holding mechanism 40 located at the closest in the depth direction of the drawing sheet of the same drawing.

Then, the robot controlling device 90 moves the tip end of the robotic arm 20b in the depth direction, and rotates the rotation shaft (not illustrated) provided inside the casing 80 on the center rotation axis L4 so that the other second holding mechanism 60 opposes horizontally to the electronic component E held by the first holding mechanism 40 located at the second closest in the depth direction of the drawing sheet of FIGS. 11(A) and 11(B). Note that the other second holding mechanism 60 may be located farther from the one second holding mechanism 60 by a distance corresponding to the spacing between the four first holding mechanisms 40. Therefore, it becomes unnecessary to move the other second holding mechanism 60 in the depth direction in FIGS. 11(A) and 11(B).

Similarly to when transferring the electronic component E to the one second holding mechanism 60 from the first holding mechanism 40 located at the closest in the depth direction of the drawing sheet of FIGS. 8(A) and 8(B), the robot controlling device 90 transfers the electronic component E to the other second holding mechanism 60 from the first holding mechanism 40 located at the second closest in the depth direction of the drawing sheet of FIGS. 11(A) and 11(B). Then, as illustrated in FIG. 11(B), the robot controlling device 90 separates, from the first holding mechanism 40, the other second holding mechanism 60 holding the electronic component E, by moving the tip end of the robotic arm 20b rightward of the drawing sheet of the same drawing.

Referring again to FIG. 1, the robot controlling device 90 controls operations of the robotic arm 20b and the holding device 30 so that the electronic components E held by the two second holding mechanisms 60 are accommodated into the second accommodating device 120 conveyed on the top of the conveyor 132. Note that, at this time, the robot controlling device 90 stops the four first holding mechanisms 40 at the position illustrated in FIG. 1. Moreover, the conveyance of the second accommodating device 120 by the conveyor 132 is in a stopped state.

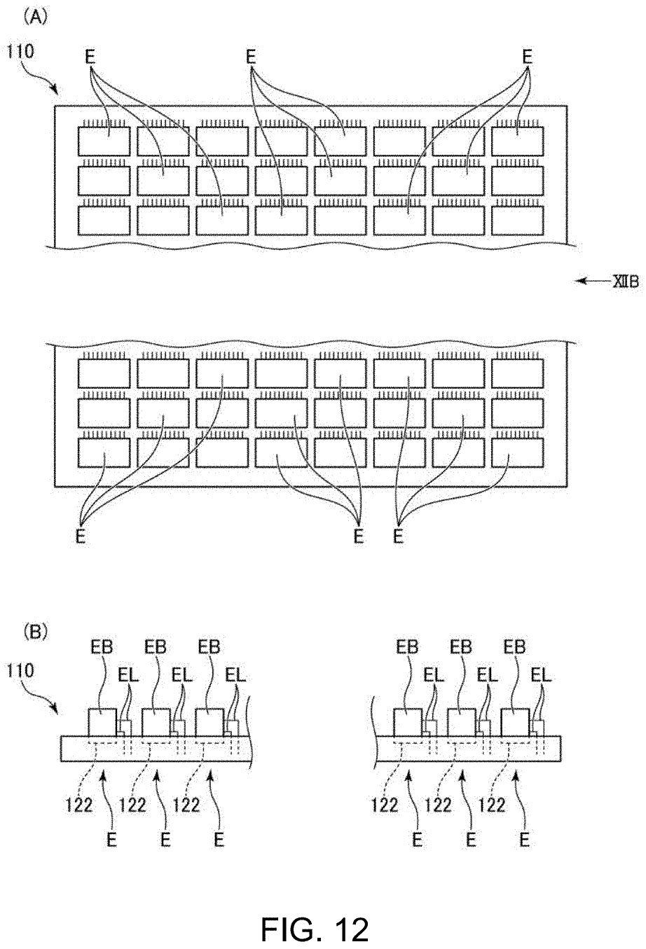

FIGS. 12(A) and 12(B) are partial schematic views illustrating a situation where a plurality of electronic components transferred by the holding device according to this embodiment and the robot provided with the same are accommodated in the second accommodating device, where FIG. 12(A) is a plan view and FIG. 12(B) is a XIIB direction view illustrated in FIG. 12(A).

As illustrated in FIG. 12(A), the second accommodating device 120 can accommodate the plurality of electronic components E parallelly in a matrix shape. In detail, the second accommodating device 120 accommodates the total of one hundred thirty-six electronic components E in the matrix of 8×17 by parallelly arranging eight electronic components E in the left-and-right direction of the drawing sheet of FIG. 12(A) and parallelly arranging 17 electronic components E in the up-and-down direction of the drawing sheet of the same drawing.

As illustrated in FIG. 12(B), in order to accommodate the electronic components E so as to parallelly arrange in the matrix of 8×17, the second accommodating device 120 has the total of one hundred thirty-six dents 122 of a shape corresponding to a front part of the electronic component E in the matrix of 8×17. As illustrated in the same drawing, the second accommodating device 120 can accommodate the one hundred thirty-six electronic components E in a state where the front part of the electronic component body EB and the tip-end parts of the twenty lead wires EL are fitted into the dents 122, and the rear part of the electronic component body EB and the base-end parts of the twenty lead wires EL are exposed.

As described above, the second accommodating device 120 can accommodate the one hundred thirty-six electronic components E in a state where the tip ends of the lead wires EL of the one hundred thirty-six electronic components E are located downwardly. Thus, by accommodating the electronic components E in the second accommodating device 120, it is not necessary to change the orientation of the electronic components E in a post process in which the electronic components E are mounted on a substrate (not illustrated). Therefore, the post process may be performed easily and promptly.

After the robot controlling device 90 accommodates the electronic components E held by the two second holding mechanisms 60 into the second accommodating device 120, it resumes the posture of the robotic arm 20b to a state illustrated in FIG. 1. Then, similarly to the above description, it transfers the remaining two electronic components E held by the first holding mechanism 40 to the two second holding mechanisms 60 and accommodates them in the second accommodating device 120. Moreover, when the electronic components E held by the four first holding mechanisms 40 are all transferred to the second holding mechanism 60, the robot controlling device 90 again makes the four first holding mechanisms 40 hold the electronic components E accommodated in the first accommodating device 110, respectively, similarly to the above description.

When the above work is repeated by the robot 10 and all the electronic components E accommodated in the first accommodating device 110 are transferred to the second accommodating device 120, the first accommodating device 110 which became empty is replaced by another first accommodating device 110 which accommodates a plurality of electronic components E, by a human labor. Moreover, when the electronic components E are accommodated in all the dents 122 of the second accommodating device 120, the second accommodating device 120 is conveyed downstream on the conveyor 132. In connection with this, another empty second accommodating device 120 is conveyed on the conveyor 132 to a location adjacent to the robot 10 from the upstream.

As described above, the robot 10 according to this embodiment can repeatedly perform the work for transferring a plurality of electronic components E from the first accommodating device 110 to the second accommodating device 120.

### Effects

The holding device 30 according to this embodiment transfers the electronic component E from the first holding mechanism 40 which is capable of holding the electronic component E by pinching the electronic component E by the pair of first members 45a and 45b in the longitudinal direction of the electronic component E (first direction) to the second holding mechanism 60 which is capable of holding the electronic component E by pinching the electronic component E by the pair of second members 65a and 65b in the height direction of the electronic component E (second direction). Therefore, when transferring the electronic component E from the first holding mechanism 40 to the second holding mechanism 60, the holding device 30 according to this embodiment can suppress a possibility that the electronic component E is dropped, for example. Note that, in this embodiment, the electronic component body EB is placed on the second member 65a, and, therefore, it can be prevented that the electronic component E is dropped also by this. As a result, the holding device 30 according to this embodiment becomes possible to securely transfer the electronic component from the first holding mechanism 40 to the second holding mechanism 60.

Since in this embodiment the electronic component E is held by the pair of first members 45a and 45b pinching the plurality of lead wires EL from outside in the parallelly-arranged direction, even if the dimension of the electronic component body EB is comparatively small, for example, it becomes possible to securely transfer the electronic component E from the first holding mechanism 40 to the second holding mechanism 60.

In this embodiment, since the second holding mechanism 60 holds the electronic component E in the state where the corner part EC of the electronic component body EB is fitted into the recess 66 formed in each of the pair of second members 65a and 65b, the electronic component E can securely be held. As a result, the holding device 30 according to this embodiment becomes possible to further securely transfer the electronic component E from the first holding mechanism 40 to the second holding mechanism 60.

Since the holding device 30 according to this embodiment is provided with the four first holding mechanisms 40, the four electronic components E can be held simultaneously by the four first holding mechanisms 40. As a result, the holding device 30 according to this embodiment becomes possible to efficiently transfer the electronic component E from the first holding mechanism 40 to the second holding mechanism 60.

In this embodiment, since the holding-device controller 94 (controlling device) is configured to be a part of the robot controlling device 90, the configuration of the robot 10 can be simplified. Moreover, since the robot controlling device 90 carries out the servo control of the robotic arms 20a and 20b (first and second robotic aims), the first holding mechanism 40, and the second holding mechanism 60, it becomes possible to accurately control the operation of the robot 10.

In this embodiment, the external force F₁ (first external force) applied to the electronic component E by the pair of first members 45a and 45b is smaller than the external force F₂ (second external force) applied to the electronic component E by the pair of second members 65a and 65b. Therefore, for example, it becomes possible to suppress that the lead wires EL which is comparatively easy to be deformed are deformed by the external force F₁. Moreover, the electronic component body EB which is comparatively difficult to be deformed may be securely held by the external force F₂.

In this embodiment, the direction in which the electronic component E is pinched by the pair of first members 45a and 45b is the longitudinal direction (first direction) of the electronic component E. The direction in which the electronic component E is pinched by the pair of second members 65a and 65b is the height direction (second direction) of the electronic component E, and the height direction is perpendicular to the longitudinal direction. Therefore, it can be prevented that the first holding mechanism 40 and the second holding mechanism 60 interfere with each other, and the electronic component E can stably be transferred from the first holding mechanism 40 to the second holding mechanism 60. As a result, the holding device 30 according to this embodiment becomes possible to further securely transfer the electronic component E from the first holding mechanism 40 to the second holding mechanism 60.

In this embodiment, since the rotation axes L1 at the base ends of the robotic arms 20a and 20b are located on the same straight line, the robot 10 can be downsized.

(Method of Controlling Holding Device 30)

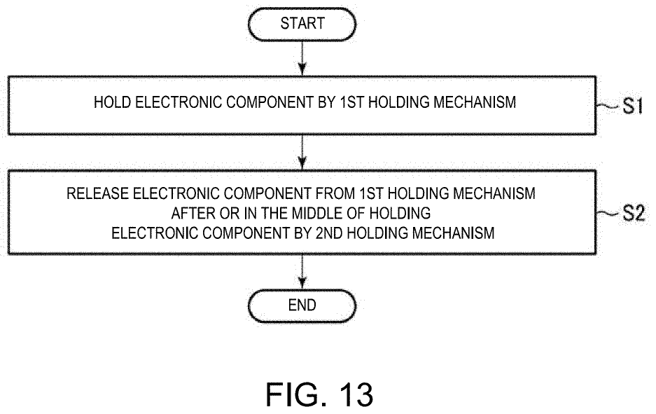

Next, a method of controlling the holding device is described mainly based on FIG. 13. FIG. 13 is a flowchart illustrating the controlling method for controlling operation of the holding device according to the above embodiment. Note that, here, one example of the controlling method for controlling operation of the holding device 30 by the robot controlling device 90 explained in the above embodiment is described.

As illustrated in FIG. 13, the robot controlling device 90 first performs Step S1 (First Step) where it holds the electronic component E by the first holding mechanism 40.

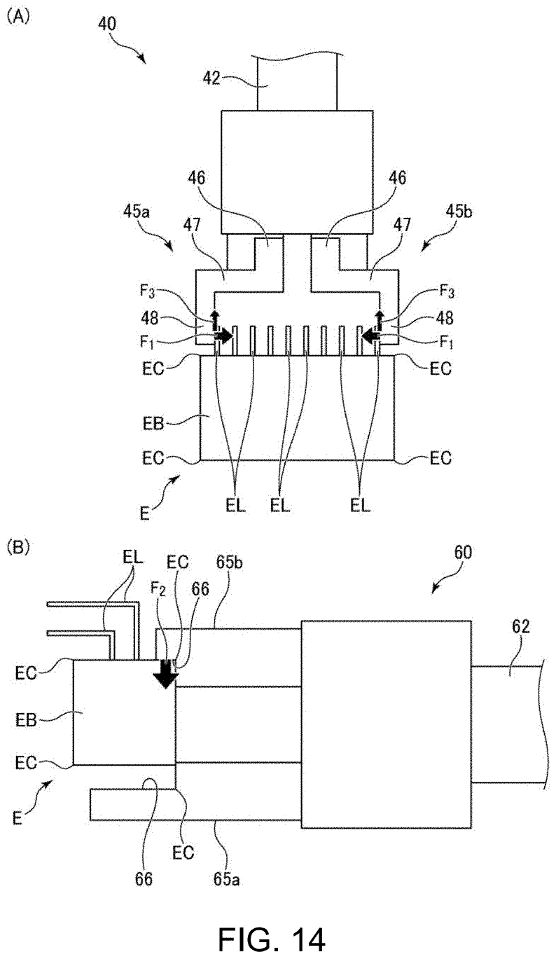

Then, after performing Step S1, the robot controlling device 90 performs Step S2 (Second Step) where it releases the electronic component E from the first holding mechanism 40 after holding the electronic component E by the second holding mechanism 60 or in the middle of holding the electronic component E. Note that the case where the electronic component E is released from the first holding mechanism 40 in the middle of holding the electronic component by the second holding mechanism 60 will be described later in detail based on FIGS. 14(A) and 14(B).

As described above, by the robot controlling device 90, the controlling method according to this embodiment can transfer the electronic component E from the first holding mechanism 40 to the second holding mechanism 60 by controlling the operation of the holding device 30.

(Modifications)

It is apparent for the person skilled in the art that many improvements and other embodiments of the present disclosure are possible from the above description. Therefore, the above description is to be interpreted only as illustration, and it is provided in order to teach the person skilled in the art the best mode that implements the present disclosure. The details of the structures and/or the functions may be changed substantially, without departing from the spirit of the present disclosure.

(First Modification)

Based on FIGS. 14(A) and 14(B), a first modification of the holding device according to the above embodiment and the robot provided with the same is described. FIGS. 14(A) and 14(B) are schematic views illustrating a situation where the first modification of the holding device according to the above embodiment and the robot provided with the same transfers the electronic component from the first holding mechanism to the second holding mechanism, where FIG. 14(A) is a view immediately before the electronic component is released from the first holding mechanism, and FIG. 14(B) is a view illustrating a state where the electronic component is about to be held by the second holding mechanism at the time of FIG. 14(A). Note that this modification only differs from the above embodiment in the mode of transferring the electronic component E from the first holding mechanism 40 to the second holding mechanism 60. Therefore, the same reference characters are given to the same parts not to repeat similar description.

In the above embodiment, the robot controlling device 90 controls the operation of the holding device 30 so that the electronic component E is released from the first holding mechanism 40, after the second holding mechanism 60 holds the electronic component E. However, without being limited to the case, the robot controlling device 90 may control the operation of the holding device 30 so that it releases the electronic component E from the first holding mechanism 40 in the middle of holding the electronic component E by the second holding mechanism 60.

In such a case, for example, as illustrated in FIGS. 14(A) and 14(B), the robot controlling device 90 moves the electronic component E downwardly by making the second member 65b contact the upper surface of the electronic component body EB in a state where the second member 65a opposes to the bottom surface of the electronic component body EB without being in contact with the bottom surface, and applying the external force F₂ to the upper surface of the electronic component body EB from the second member 65b.

At this time, the external force F₂ has a magnitude which can move the electronic component E held by the first holding mechanism 40 downwardly (second direction), against the external force F₁ (in detail, a frictional force F3 caused between the lead wires EL located at the left end and the first member 45a, and a frictional force F3 caused between the lead wires EL located at the right end and the first member 45b, in FIGS. 14(A) and 14(B)).

Then, before the second member 65a contacts the bottom surface of the electronic component body EB, the twenty lead wires EL may slip out of the pair of first members 45a and 45b. In such a mode, the robot controlling device 90 may release the electronic component E from the first holding mechanism 40 in the middle of holding the electronic component by the second holding mechanism 60. Note that, in such a case, since the external force F₁ is smaller than the external force F₂, it becomes possible to suppress that the downward movement of the second holding mechanism 60 is impeded by the external force F₁. Therefore, the holding device 30 becomes possible to smoothly transfer the electronic component E from the first holding mechanism 40 to the second holding mechanism 60.

Referring again to FIGS. 9(A) and 9(B), the robot controlling device 90 may control the operation of the holding device 30 so that it moves the pair of second members 65a and 65b downwardly, while applying the external force F₁ to the plurality of lead wires EL by the pair of first members 45a and 45b. In such a mode, the robot controlling device 90 may control the operation of the holding device 30 so that it releases the electronic component E from the first holding mechanism 40, after the second holding mechanism 60 holds the electronic component E.

(Second Modification)

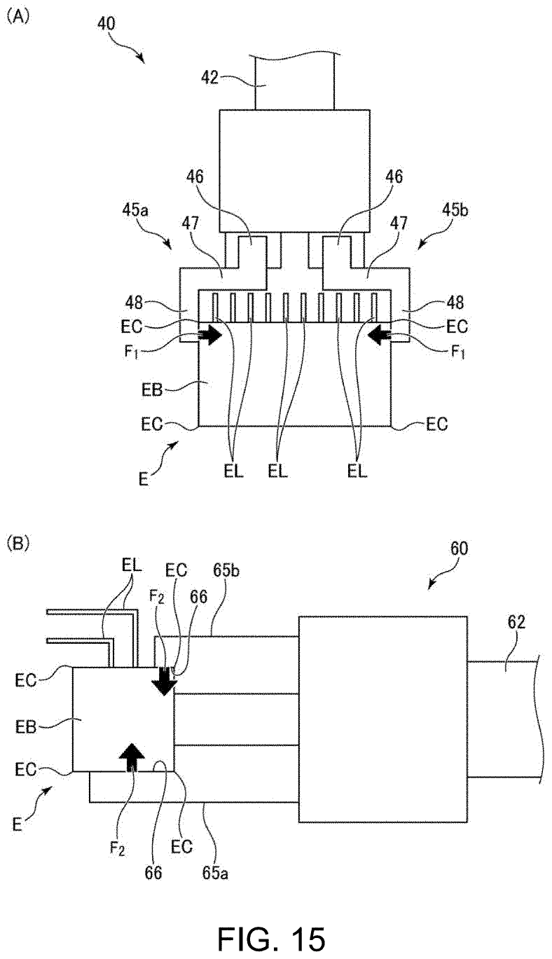

Based on FIGS. 15(A) and 15(B), a first modification of the holding device according to the above embodiment and the robot provided with the same is described. FIGS. 15(A) and 15(B) are schematic views illustrating a situation where the modification of the holding device according to the above embodiment and the robot provided with the same transfers the electronic component from the first holding mechanism to the second holding mechanism, where FIG. 15(A) is a view immediately before the electronic component is released from the first holding mechanism, and FIG. 15(B) is a view illustrating a state where the electronic component is held by the second holding mechanism at the time of FIG. 15(A). Note that this modification only differs from the above embodiment in the mode of holding the electronic component E by the first holding mechanism 40. Therefore, the same reference characters are given to the same parts not to repeat similar description.

As illustrated in FIG. 15(A), in this modification, the first holding mechanism 40 can hold the electronic component body EB by pinching the electronic component body EB in the longitudinal direction of the electronic component body EB by the pair of first members 45a and 45b. Thus, in this modification, the electronic component E can be transferred from the first holding mechanism 40 to the second holding mechanism 60 by the first holding mechanism 40 holding the electronic component E, without deforming the lead wires EL.

(Third Modification)

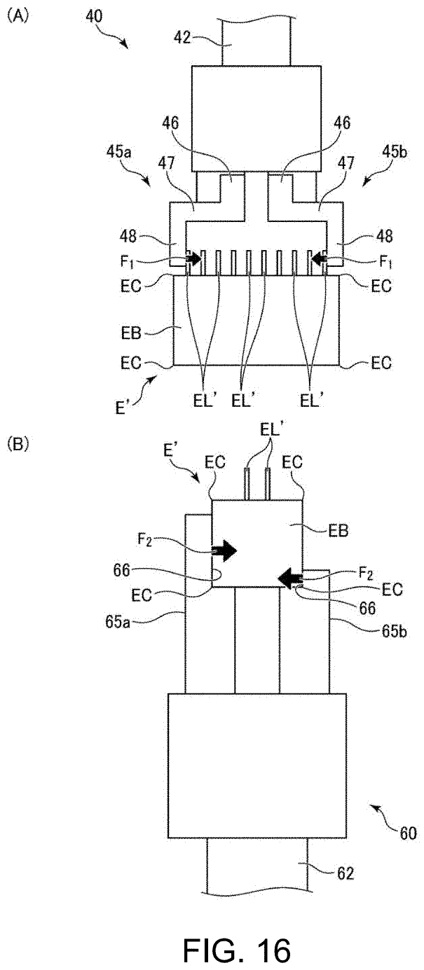

Based on FIGS. 16(A) and 16(B), a first modification of the holding device according to the above embodiment and the robot provided with the same is described. FIGS. 16(A) and 16(B) are schematic views illustrating a situation where the third modification of the holding device according to the above embodiment and the robot provided with the same transfers the electronic component from the first holding mechanism to the second holding mechanism, where FIG. 16(A) is a view immediately before the electronic component is released from the first holding mechanism, and FIG. 16(B) is a view illustrating a state where the electronic component is held by the second holding mechanism at the time of FIG. 16(A). Note that this modification only differs from the above embodiment in the shape of lead wires EL and the mode of holding the electronic component E by the second holding mechanism 60. Therefore, the same reference characters are given to the same parts not to repeat similar description.

In the above embodiment and its modifications, the lead wires EL has the L-shape. However, without being limited to the case, lead wires EL′ may be straight as illustrated in FIGS. 16(A) and 16(B). In such a case, for example, as illustrated in FIG. 16(B), the second holding mechanism 60 may apply the external force F₂, by the second member 65a which contacts the front surface of the electronic component body EB (that is, a surface located on the left side of the drawing sheet of FIG. 16(B)), toward the opposite side of the electronic component body EB in the front-and-rear direction (second direction) (that is, toward the rear surface of the electronic component body EB). Moreover, the second holding mechanism 60 may apply the external force F₂, by the second member 65b which contacts the rear surface of the electronic component body EB (that is, a surface located on the right side of the drawing sheet of FIG. 16(B)), toward the opposite side of the electronic component body EB in the front-and-rear direction (that is, toward the front surface of the electronic component body EB).

The second holding mechanism 60 may hold an electronic component E′ by applying the external force F₂ to the electronic component body EB as described above. Therefore, the second holding mechanism 60 becomes possible to accommodate the electronic component E in the second accommodating device 120 in a state where the tip ends of the lead wires EL′ are oriented downwardly. As a result, in the post process where the electronic component E′ is mounted on the substrate (not illustrated), it is not necessary to change the orientation of the electronic component E′. Therefore, the post process may be performed easily and promptly.

Here, in the above embodiment and the first and second modifications, the second holding mechanism 60 holds, the electronic component E by pinching the electronic component body EB in the height direction by the pair of second members 65a and 65b. That is, in the above embodiment and the first and second modifications, the second direction is the up-and-down direction of the drawing sheet of FIG. 16(B).

On the other hand, in the third modification, the first holding mechanism 40 holds the electronic component E′ by pinching the electronic component body EB in the front-and-rear direction (that is, in the left-and-right direction of the drawing sheet of FIG. 16(B)) by the pair of second members 65a and 65b. Thus, in this modification, the second direction is the left-and-right direction of the drawing sheet of FIG. 16(B). Even in such a case, since the second direction differs from the first direction which is in agreement with the longitudinal direction of the electronic component E′ (that is, the depth direction of the drawing sheet of FIG. 16(B)), the electronic component E becomes possible to be securely transferred from the first holding mechanism 40 to the second holding mechanism 60.

Note that the first direction and the second direction are not limited to the directions described above, but may be other directions as long as the second direction differs from the first direction. For example, the first holding mechanism 40 may hold the electronic component E by pinching the electronic component body EB in the height direction by the pair of first members 45a and 45b, and the second holding mechanism 60 may hold the electronic component E by pinching, by the pair of second members 65a and 65b, the plurality of lead wires EL in the parallelly-arranged direction from outside in the parallelly-arranged direction.

(Other Modifications)

In the above embodiment and its modifications, the first direction is in agreement with the longitudinal direction of the electronic component E, the second direction is in agreement with the height direction of the electronic component E, and the first direction and the second direction are perpendicular to each other. However, without being limited to this case, for example, the first direction may be in agreement with the height direction of the electronic component E, and the second direction may be in agreement with the longitudinal direction of the electronic component E, or each of the first direction and the second direction may be in agreement with another direction. Moreover, the second direction does not need to be perpendicular to the first direction, as long as the second direction differs from the first direction.

In the above embodiment, the holding device 30 is provided with the four first holding mechanisms 40. However, without being limited to the case, the holding device 30 may be provided with one or more and three or less first holding mechanisms 40, or may be provided with five or more. Moreover, in the above embodiment, the holding device 30 is provided with the two second holding mechanisms 60. However, without being limited to the case, the holding device 30 may be provided with only one second holding mechanism 60, or may be provided with three or more.

In the above embodiment and its modifications, the electronic component E has the rectangular-parallelepiped-shaped electronic component body EB, and the plurality of lead wires EL provided to the upper surface of the electronic component body EB. However, without being limited to the case, the electronic component may have, for example, terminals which are fitted into recesses formed in the bottom surface of the electronic component body EB, instead of the lead wires EL.

In the above embodiment and its modifications, as illustrated in FIG. 9 etc., the parts of the tip-end parts 48 of the pair of first members 45a and 45b which contact the electronic component E are flat. However, without being limited to this case, the parts of the tip-end parts 48 of the pair of first members 45a and 45b which contact the electronic component E may be formed with recesses having a shape corresponding to the electronic component E. Note that the recess may be formed only in one of the pair of first members 45a and 45b.

In the above embodiment and its modifications, the pair of second members 65a and 65b are each formed with the recess 66 of the shape corresponding to the corner part EC of the electronic component body EB. However, without being limited to this case, each of the pair of second members 65a and 65b may not be formed with the recess 66, or only one of the pair of second members 65a and 65b may be formed with the recess 66.

In the above embodiment and its modifications, the pair of first members 45a and 45b are each movable in the first direction by the first holding mechanism 40 having the rack-and-pinion structure. However, without being limited to the case, for example, only one of the pair of first members 45a and 45b may be connected to the servomotor and the pinion and movable in the first direction, and the other of the pair of first members 45a and 45b may be fixed, or the pair of first members 45a and 45b may be relatively movable in the first direction by other modes. Note that since the similar things can be said for the pair of second members 65a and 65b, description is not repeated here.

In the above embodiment and its modifications, each of the robotic arms 20a and 20b has the four joint axes JT1-JT4. However, without being limited to the case, each of the robotic arms 20a and 20b may have at least one joint axis.

In the above embodiment and its modifications, the rotation axis of the base end of each of the robotic arms 20a and 20b is located on the same straight line. However, without being limited to the case, the rotation axis of the base end of each of the robotic arms 20a and 20b may not be located on the same straight line. Moreover, in the above embodiment and its modifications, one robot 10 is provided with the robotic arms 20a and 20b. However, without being limited to this case, for example, a first robot may be provided with the robotic arm 20a, and a second robot which is provided separately from the first robot may be provided with the robotic arm 20b.

In the above embodiment and its modifications, the robot 10 has the structure illustrated in FIG. 2. However, without being limited to this case, the robot 10 according to the present disclosure may be configured as a vertical articulated robot, or may be configured as a horizontal articulated robot, for example. Alternatively, for example, the robot 10 may be configured as a polar-coordinate robot, may be configured as a cylindrical-coordinate robot, may be configured as a Cartesian-coordinate robot, or may be configured as other robots.

In the above embodiment and its modifications, the holding device 30 and the robot 10 provided with the same are used for transferring the plurality of electronic components E from the first accommodating device 110 to the second accommodating device 120. However, without being limited to the case, the holding device 30 and the robot 10 provided with the same may be used for mounting the plurality of electronic components E accommodated in the first accommodating device 110 onto a substrate (not illustrated), for example. In such a case, after holding the electronic component E accommodated in the first accommodating device 110 by the first holding mechanism 40, the robot controlling device 90 may transfer the electronic component E from the first holding mechanism 40 to the second holding mechanism 60, and may mount the electronic component E onto the substrate by the second holding mechanism 60. Alternatively, the holding device 30 and the robot 10 provided with the same may be used for performing other works, as long as the works include the work for transferring the electronic component E from the first holding mechanism 40 to the second holding mechanism 60.

### DESCRIPTION OF REFERENCE CHARACTERS

10 Robot
12 Pedestal
14 Base Shaft
20 Robotic Arm
22 First Link
24 Second Link
26 Wrist
27 Mechanical Interface
29 Servomotor
30 Holding Device
40 First Holding Mechanism
42 Shaft Member
45 First Member
46 Base-end Part
47 Center Part
48 Tip-end Part
49 Servomotor
60 Second Holding Mechanism
62 Shaft Member
65 Second Member
66 Recess
70 Attaching Part
71 Base Shaft Member
72 Center Member
75 Intervening Mechanism
76 First Base-end Member
77 Second Base-end Member
78 Connecting Member
79 Plate-like Member
80 Casing
81 Tip-end Member
90 Robot Controlling Device
92 Robotic-arm Controller
94 Holding-device Controller
110 First Accommodating Device
120 Second Accommodating Device
130 Loading Table
132 Conveyor
JT Joint Axis
L Rotation Axis
E Electronic Component
EB Electronic Component Body
EL Lead Wire
EC Corner Part

1. A holding device configured to hold an electronic component, comprising:
a first holding mechanism having a pair of first members opposing to each other in a first direction and relatively movable in the first direction, and configured to hold the electronic component by pinching the electronic component in the first direction by the pair of first members;
a second holding mechanism having a pair of second members opposing to each other in a second direction different from the first direction and relatively movable in the second direction, and configured to hold the electronic component by pinching the electronic component in the second direction by the pair of second members; and
a controlling device configured to control operations of the first and second holding mechanisms,
wherein the controlling device controls the operations of the first and second holding mechanisms so that the electronic component is released from the first holding mechanism after or in the middle of holding the electronic component by the second holding mechanism in a state where the electronic component is held by the first holding mechanism.

2. The holding device of claim 1, wherein the electronic component has an electronic component body, and a lead wire extending from the electronic component body,
wherein the first holding mechanism holds the electronic component by pinching, by the pair of first members, the lead wire in a radial direction of the lead wire that is in agreement with the first direction, and
wherein the second holding mechanism holds the electronic component by pinching, by the pair of second members, the electronic component body in a height direction of the electronic component body that is in agreement with the second direction.

3. The holding device of claim 2, wherein the electronic component has a plurality of lead wires, the plurality of lead wires being arranged parallelly in a parallelly-arranged direction that is in agreement with the first direction and the radial direction of the lead wires, and
wherein the first holding mechanism holds the electronic component by pinching, by the pair of first members, the plurality of lead wires in the parallelly-arranged direction from outside in the parallelly-arranged direction.

4. The holding device of claim 2, wherein the electronic component body has a corner part at least in one of both ends in the height direction,
wherein the pair of second members have a recess of a shape corresponding to the corner part, and
wherein the second holding mechanism holds the electronic component in a state where the corner part is fitted into the recess.

5. The holding device of any one of claim 1, provided with a plurality of first holding mechanisms.

6. The holding device of any one of claim 1, wherein, when holding the electronic component, the first holding mechanism applies a first external force to the electronic component from each of the pair of first members,
wherein, when holding the electronic component, the second holding mechanism applies a second external force to the electronic component from each of the pair of second members, and
wherein the second external force has a magnitude capable of moving in the second direction the electronic component held by the first holding mechanism, against the first external force.

7. The holding device of any one of claim 1, wherein the second direction is perpendicular to the first direction.

8. A robot, comprising:
the holding device of any one of claim 1;
a first robotic arm provided with the first holding mechanism at a tip end thereof and having at least one joint axis;
a second robotic arm provided with the second holding mechanism at a tip end thereof and having at least one joint axis; and
a robot controlling device configured to control operations of the first and second robotic arms.

9. The robot of claim 8, wherein rotation axes of the first and second robotic arms at base ends thereof are located on the same straight line.

10. The robot of claim 8, wherein the at least one joint axis of the first robotic arm is provided with a first servomotor configured to rotate itself, and the at least one joint axis of the second robotic arm is provided with a second servomotor configured to rotated itself,
wherein the first holding mechanism is provided with a third servomotor configured to drive the pair of first members, and the second holding mechanism is provided with a fourth servomotor configured to drive the pair of second members, and
wherein the controlling device is configured as a part of the robot controlling device, and the robot controlling device servo-controls the first and second robotic arms, and the first and second holding mechanisms by using the first to fourth servomotors.

11. A method of controlling a holding device configured to hold an electronic component, the holding device including:
a first holding mechanism having a pair of first members opposing to each other in a first direction and relatively movable in the first direction, and configured to hold the electronic component by pinching the electronic component in the first direction by the pair of first members;
a second holding mechanism having a pair of second members opposing to each other in a second direction different from the first direction and relatively movable in the second direction, and configured to hold the electronic component by pinching the electronic component in the second direction by the pair of second members; and
a controlling device configured to control operations of the first and second holding mechanisms,
the method comprising the steps of:
holding the electronic component by the first holding mechanism; and
releasing the electronic component from the first holding mechanism, after or in the middle of holding the electronic component by the second holding mechanism.
